(19) United States
(12) Patent Application Publication
(10) Pub. No.: US 2007/0133181 A1
(43) Pub. Date: Jun. 14, 2007

(54) Printed Card Device and Method

(76) Inventors: Kim Griesmann, St. Louis Park, MN (US); Bill Schultz, St. Louis Park, MN (US); Bob Montgomery, St. Louis Park, MN (US); David Milne, Blaine, MN (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/275,073

(22) Filed: Dec. 8, 2005

(51) Int. Cl. H05K 1/14

(52) U.S. Cl. 361/737

(57) ABSTRACT

A card assembly device and method are shown. Card assemblies and methods described have the ability to stiffen a card assembly, while still maintaining the ability to encode data on a data strip. Another advantage of card assemblies as shown includes an integral card and carrier formation, which reduces manufacturing costs. Card assemblies are also shown that include return mail portions.

### TECHNICAL FIELD

This invention relates to printed card assemblies and methods of forming printed card assemblies.

### BACKGROUND

Printed card assemblies are used for a number of applications. Some examples include stored value cards such as merchant gift cards or long distance phone cards. Other examples include various types of membership cards or cards for direct mailings. Although a list of card assembly types is included, the list is not intended to be exhaustive.

One concern that exists in the card assembly industry includes the cost of materials and manufacturing in card assemblies. Another concern includes ease of encoding magnetic strips. Another concern includes structural stability of card assemblies.

U.S. Pat. No. 5,918,909 shows one type of card assembly. One concern with designs shown in the '909 patent includes the cost of manufacturing both a card and a card carrier separately and further costs associated with later attaching the card to the card carrier. The multiple operations required in the '909 patent increase the cost of the final card assembly.

U.S. Pat. Nos. 5,921,584 and 5,720,158 show other types of card assemblies. Card assemblies in the '584 and '158 patents include card carriers and cards that are formed integrally with each other, therefore reducing the manufacturing cost. One concern with designs shown in the '584 and '158 patents includes the structural stability of the cards as they are attached to card carriers. It is desirable to make a robust connection between the card and card carrier to prevent unwanted separation before the end user intends to separate the card. A technical hurdle involved in structure of the card assembly has been encoding and reading data from cards with a data strip on one side such as a magnetic strip. The '584 and the '158 patent discuss how the side portion of the card are exposed to allow the card to be encoded without removing the card from the card carrier.

What is needed is an inexpensive card assembly that includes increased structural stability. What is also needed is a product and method that permits encoding while maintaining structural stability.

### BRIEF DESCRIPTION OF THE DRAWINGS

FIG. 1A shows a front side of a card assembly according to an embodiment of the invention.

FIG. 1B shows a back side of the card assembly from FIG. 1A according to an embodiment of the invention.

FIG. 2 shows a card encoding operation according to an embodiment of the invention.

FIG. 3 shows a block diagram of a card encoder according to an embodiment of the invention.

FIG. 4A shows a front side of another card assembly according to an embodiment of the invention.

FIG. 4B shows a back side of the card assembly from FIG. 4A according to an embodiment of the invention.

FIG. 5 shows a flow diagram of one method according to an embodiment of the invention.

### DETAILED DESCRIPTION

In the following detailed description, reference is made to the accompanying drawings which form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, or logical changes, etc. may be made without departing from the scope of the present invention.

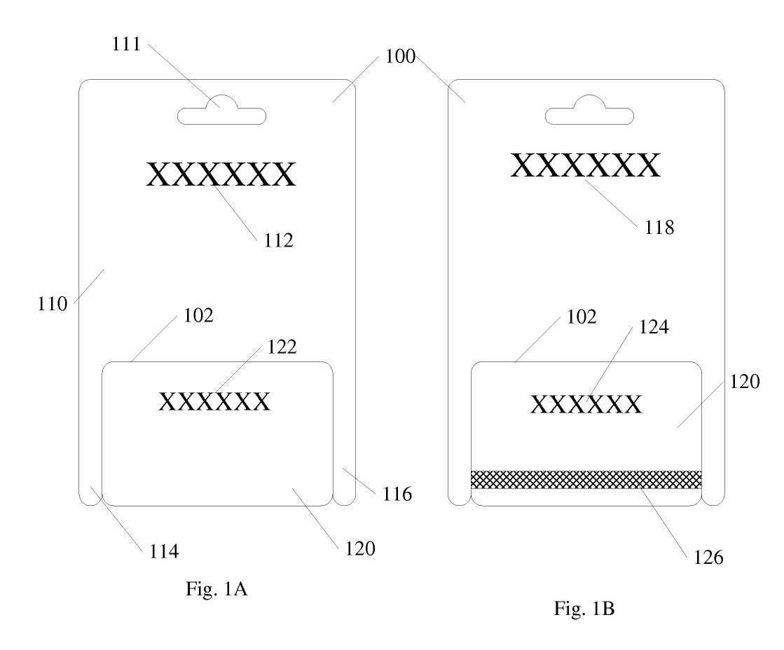

FIG. 1A and 1B show a front and back side respectively of a card assembly 100 according to an embodiment of the invention. The card assembly 100 includes a card carrier 110 and a card 120. In one embodiment, the card includes a CR-80 sized card. In one embodiment, the card 120 and card carrier 110 are integrally formed from a single sheet of material. In one embodiment, the material includes plastic. Other materials may include cardboard, plastic laminated cardboard, etc. A weakened portion 102 is located at an interface between the card 120 and the card carrier 110. In one embodiment, the weakened portion 102 includes a scored portion. Other embodiments of weakened portions 102 include perforated lines, etc. In one embodiment, such as a gift card or phone card embodiment, an aperture 111 is included for card display from a peg, etc. Although a particular geometry of aperture 111 is shown in FIG. 1A, the invention is not so limited. Other shapes of holes, slots, etc. are also within the scope of the invention.

In one embodiment, a first stiffening portion 114 and a second stiffening portion 116 are included as a part of the card carrier 110. The first and second stiffening portions 114, 116 provide a robust interface between the card 120 and the card carrier 110. In one embodiment, features such as the first and second stiffening portions 114, 116 help to prevent unwanted detachment of the card 120 from the card carrier 110 before an end user desires.

In one embodiment, images 112 are printed on the card carrier 110 and images 122 are printed on the card 120. Examples of images include text, numbers pictures, etc. In one embodiment, the images include merchant identification. In one embodiment, the images include promotional materials. In one embodiment the images include instructions for use of the card assembly 100. In one embodiment, image text includes unique customer data such as an address and/or account number for direct mailing purposes. Although a number of possible images are listed, the invention is not so limited. Although the images in FIG. 1A are shown oriented parallel to a long edge of the card 120, the invention is not so limited. Other orientations of images include parallel to a long edge of the card carrier 110.

Figure 1B shows a back side of the card assembly 100 from FIG. 1A. A data strip 126 is shown located transversely between the first and second stiffening portions 114, 116. One example of a useful data strip includes a magnetic strip. One of ordinary skill in the art, having the benefit of the present disclosure will recognize that other data storing media are also within the scope of the invention.

Similar to the front side of the card assembly 100 discussed under FIG. 1A, in one embodiment the side shown in Figure 1B includes images printed onto the card assembly 100. Images 118 are shown printed on the card carrier 110, and images 124 are shown printed on the card 120. Although images are shown printed on both sides of both the card 120 and the card carrier 110, the invention is not so limited. Images such as text or pictures, etc. may be printed in all location shown, only in selected locations shown, in other locations not shown, etc.

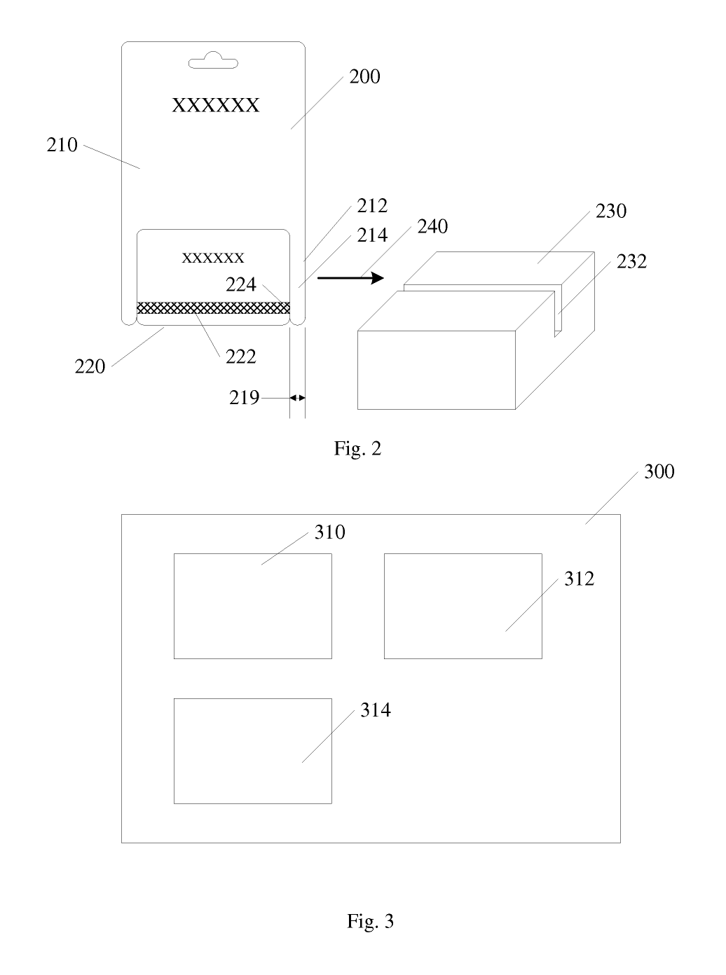

FIG. 2 shows an encoding operation according to an embodiment of the invention. A card assembly 200 similar to embodiments described above is passed through an encoder 230 along direction 240 in one method of operation. In one embodiment, a record head (not shown) is located within a slot 232 of the encoder 230. As the card assembly 200 passes through the slot 232, a sensor detects a leading edge 212 of the card assembly 200. In one embodiment, the leading edge 212 includes an edge of a stiffening portion 214.

In one embodiment, the encoder pauses for an amount of time sufficient for a width 219 of the stiffening portion 214 to pass the recording head. In one embodiment, the recording head is then activated and begins encoding data on a leading edge 224 of a data strip 222.

FIG. 3 shows a block diagram of an encoder 300 that is capable of use in an operation such as described in FIG. 2. An edge detector 310 is included in the encoder 300. Examples of edge detectors include optical detectors, electrical detectors, mechanical detectors, etc. The encoder 300 also includes an operation circuit 312, and a record head 314. As described above, in one embodiment, the operation circuit uses data supplied by the edge detector 310 to time and actuate the record head 314. In selected embodiments, the encoder 300 includes additional operations such as a read station to verify data that was written by the record head 314. In one embodiment, the encoder 300 includes an ability to apply a scratch off coating over a portion of the card, such as a personal identification number (PIN).

One advantage of embodiments described above includes low cost of manufacturing a card assembly due to integral forming of a card and card carrier. Another advantage of embodiments described above includes enhances structural integrity of the card assembly due to features such as stiffening portions. Another advantage of embodiments described above includes an ability to encode a data strip on a card while maintaining structural integrity. Features such as an edge detector and timing circuitry allow ease of encoding in one embodiment.

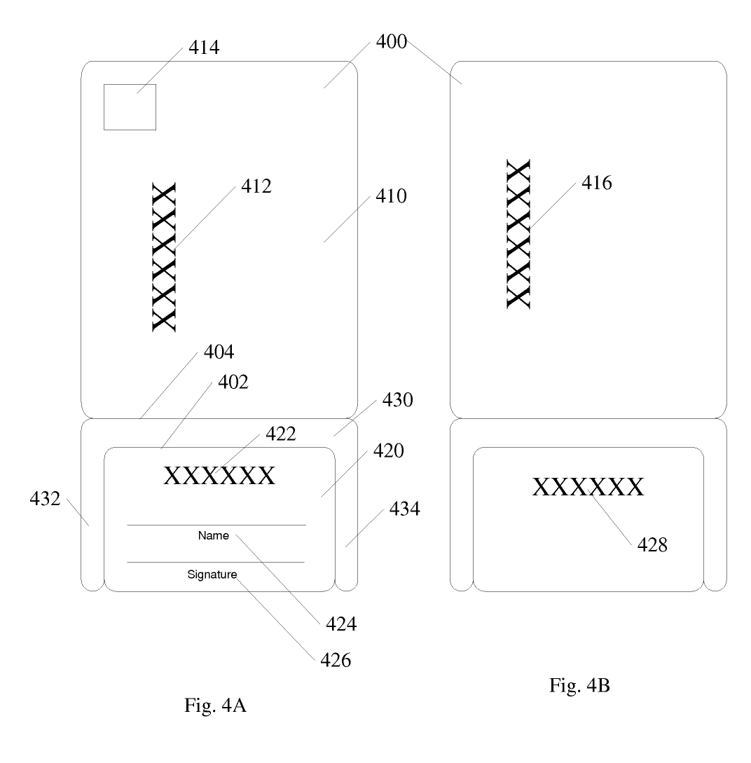

FIG. 4A shows an embodiment of another card assembly 400 according to an embodiment of the invention. The card assembly 400 includes a return mail portion 410, a card portion 420 and a carrier portion 430. In one embodiment, the return mail portion 410, the card portion 420 and the carrier portion 430 are integrally formed from a single sheet of material. In one embodiment, the material includes plastic. Other materials may include cardboard, plastic laminated cardboard, etc. A first weakened portion 402 is shown at an interface between the card 420 and the carrier 430. A second weakened portion 404 is shown at an interface between the carrier 430 and the return mail portion 410. In one embodiment, the weakened portions 402, 404 include a scored portion. Other embodiments of weakened portions 402, 404 include perforated lines, etc.

Similar to embodiments described above, selected images are printed on the card assembly 400 including text and/or pictures, etc. Image 412 is shown located on the return mail portion 410. Image 422 is shown located on the card 420. Also shown in FIG. 4B, are images 416 and 428 located on a backside of the card assembly 400. As discussed above although various orientations an locations of images are shown for examples, the invention is not so limited.

In one embodiment, the return mail portion 410 includes a “postage paid” image 414. In one embodiment, at least one information entry area is included on the card 420. FIG. 4A shows a “name” blank 424 and a “signature” blank 426 that allow a user to enter their personal information onto the card 420. In one embodiment other information entry areas are included on the return mail portion 410. In one embodiment, an information entry area is included within the image 416 on the back of the return mail portion 410.

In one embodiment, the carrier 430 includes a first stiffening portion 432 and a second stiffening portion 434. The first and second stiffening portions 432, 434 provide a robust interface between the card 420 and the carrier 430. In one embodiment, features such as the first and second stiffening portions 432, 434 help to prevent unwanted detachment of the card 430 from the carrier 430 before an end user desires.

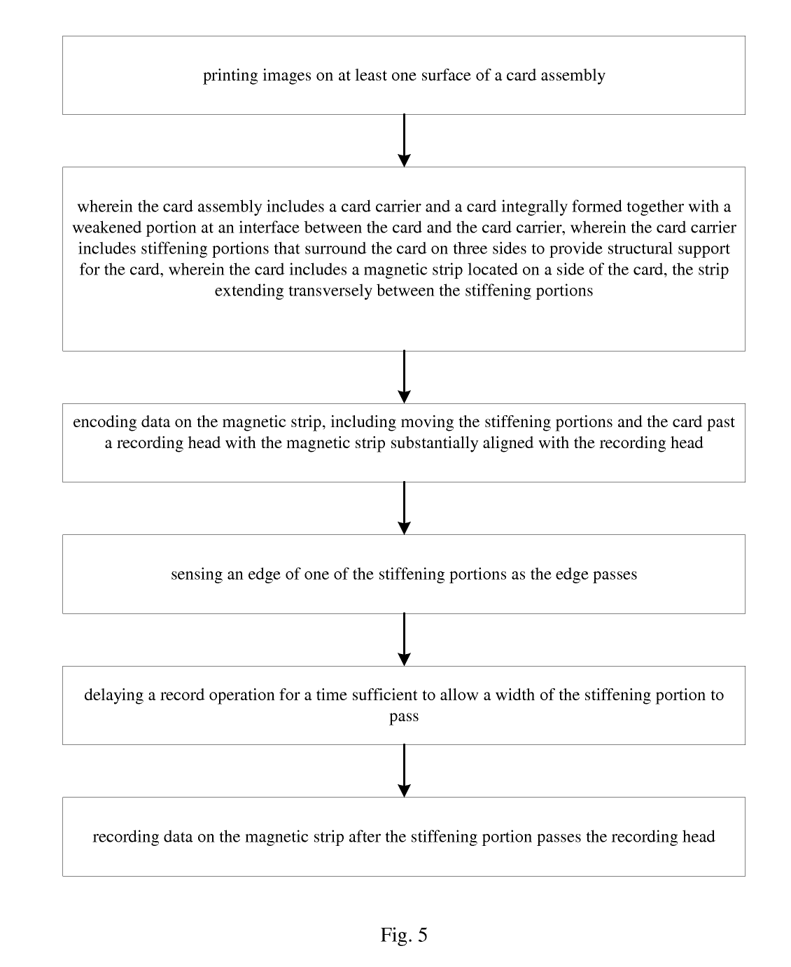

FIG. 5 shows a flow diagram of one possible card assembly method according to an embodiment of the invention. An integrally formed card assembly is provided similar to card assemblies described in embodiments above. Images such as text and/or pictures, etc. are printed onto portions of the card assembly as described above. Stiffening portions as described above are included in the card assembly in one embodiment.

A data strip such as a magnetic strip is attached to the card for encoding customer information. In one method, as shown in FIG. 5, an edge of one of the stiffening portions is sensed by an encoder as the edge passes by. An operation circuit delays a record operation for a time sufficient to allow a width of the stiffening portion to pass the recording head. The recording head is then activated to begin encoding data on the strip. A problem such as a recording head trying to record data over a stiffening portion instead of a data strip is avoided by using a delay once the stiffening portion is sensed.

### Conclusion

Embodiments of card assemblies and methods as described above have a number of advantages. One advantage of this configuration includes the ability to stiffen the card assembly, while still maintaining the ability to encode data on a data strip. Another advantage of card assemblies as described above includes integral card and carrier formation, which reduces manufacturing costs.

While a number of advantages of embodiments of the invention are described, the above lists are not intended to be exhaustive. Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. It is to be understood that the above description is intended to be illustrative, and not restrictive. Combinations of the above embodiments, and other embodiments will be apparent to those of skill in the art upon reviewing the above description. The scope of the invention includes any other applications in which the above structures and methods are used. The scope of the invention should be determined with reference to the appended claims, along with the full scope of equivalents to which such claims are entitled.

I claim:

1. A printed card assembly, comprising:
a card carrier;
a card integrally formed with the card carrier;
wherein the card carrier includes stiffening portions that surround the card on three sides to provide structural support for the card;
a structurally weakened feature located at an interface between the card carrier and the card; and
a magnetic strip located on a side of the card, the strip extending transversely between the stiffening portions.

2. The printed card assembly of claim 1, wherein the card includes a CR-80 sized card.

3. The printed card assembly of claim 1, wherein the card includes a long distance telephone card.

4. The printed card assembly of claim 1, wherein the card includes a customer loyalty card.

5. The printed card assembly of claim 1, wherein the card includes a membership card.

6. The printed card assembly of claim 1, wherein the card and the card carrier are formed from a single plastic sheet.

7. A printed card assembly, comprising:
a carrier;
a return mail portion integrally formed with the carrier;
a card integrally formed with the carrier;
wherein the carrier includes stiffening portions that surround the card on three sides to provide structural support for the card;
a structurally weakened feature located at an interface between the carrier and the card;
a structurally weakened feature located at an interface between the carrier and the return mail portion; and
an information area to allow a user to write personal information.

8. The printed card assembly of claim 7, wherein the card and the card carrier are formed from a single plastic sheet.

9. The printed card assembly of claim 7, wherein the card includes a CR-80 sized card.

10. A method of forming a printed card assembly, comprising:
printing images on at least one surface of a card assembly;
wherein the card assembly includes a card carrier and a card integrally formed together with a weakened portion at an interface between the card and the card carrier;
wherein the card carrier includes stiffening portions that surround the card on three sides to provide structural support for the card;
wherein the card includes a magnetic strip located on a side of the card, the strip extending transversely between the stiffening portions;
encoding data on the magnetic strip, including;
moving the stiffening portions and the card past a recording head with the magnetic strip substantially aligned with the recording head;
sensing an edge of one of the stiffening portions as the edge passes;
delaying a record operation for a time sufficient to allow a width of the stiffening portion to pass; and
recording data on the magnetic strip after the stiffening portion passes the recording head.

11. The method of claim 10, wherein sensing an edge of one of the stiffening portions includes optical sensing of the edge.

12. The method of claim 10, wherein recording data on the magnetic strip includes recording telephone card data on the magnetic strip.

13. The method of claim 10, wherein recording data on the magnetic strip includes recording unique customer data on the magnetic strip.
